(19) United States
(12) Patent Application Publication
(10) Pub. No.: US 2024/0413106 A1
(43) Pub. Date: Dec. 12, 2024

(54) SEMICONDUCTOR DEVICE AND METHOD OF FABRICATING THE SAME

(71) Applicant: United Microelectronics Corp., Hsinchu (TW)

(72) Inventor: Chien-Ming Lai, Tainan City (TW)

(73) Assignee: United Microelectronics Corp., Hsinchu (TW)

(21) Appl. No.: 18/350,755

(22) Filed: Jul. 12, 2023

(30) Foreign Application Priority Data
Jun. 8, 2023 (TW) 112121381

(51) Int. Cl. H01L 23/00; H01L 25/065

(52) U.S. Cl. CPC H01L 24/05; H01L 24/03; H01L 24/06; H01L 24/08; H01L 24/80; H01L 25/0657; H01L 2224/02181; H01L 2224/03616; H01L 2224/05005; H01L 2224/05541; H01L 2224/0603; H01L 2224/08145; H01L 2224/80895; H01L 2224/80896; H01L 2225/06527; H01L 2924/1205; H01L 2924/1206; H01L 2924/1207

(57) ABSTRACT

A semiconductor device includes a substrate, a bonding structure and an adjustment layer. A bonding structure is located over the substrate. The adjustment layer is located on a bonding pad of the bonding structure.

### CROSS-REFERENCE TO RELATED APPLICATION

This application claims the priority benefit of Taiwan application serial no. 112121381, filed on Jun. 8, 2023. The entirety of the above-mentioned patent application is hereby incorporated by reference herein and made a part of the specification.

### BACKGROUND

### Technical Field

The present disclosure relates to an integrated circuit and a method of fabricating the same, and in particular to a semiconductor device and a method of fabricating the same.

### Description of Related Art

With the rapid development of the electronic industry, the electronic device is becoming smaller and the level of integration is getting higher. Packaging technology has been continuously researched and developed to integrate more and smaller devices into a given area so as to provide high performance, large capacity, miniaturization and light weight. The hybrid bonding process is an advanced semiconductor packaging technology, which is configured to stack and bond multiple semiconductor dies. However, the existing hybrid bonding process technology is complicated and the process cost is relatively high.

### SUMMARY

Embodiments of the present disclosure provide various units/dies of semiconductor devices, which can be bonded to each other with less complexity, high process flexibility and uniformity.

An embodiment of the present disclosure provides a semiconductor device that includes a substrate, a bonding structure, and an adjustment layer. The bonding structure is located over the substrate. The adjustment layer is located on a bonding pad of the bonding structure.

An embodiment of the present disclosure provides a semiconductor device that includes

a first die, a second die, a bonding structure, and a first adjustment layer. The first die includes a first interconnection structure. The second die includes a second interconnection structure. The first die is bonded to the second die through the bonding structure. The first adjustment layer is located between a first bonding pad of the bonding structure and a first topmost conductive layer of the first interconnection structure.

An embodiment of the present disclosure provides a method of fabricating a semiconductor device that includes the following steps. A first die is formed, and the first die includes a first interconnection structure. A second die is formed, and the second die includes a second interconnection structure. The first die is bonded to the second die through a bonding structure. A first adjustment layer is formed between a first bonding pad of the bonding structure and a first topmost conductive layer of the first interconnection structure.

Based on the above, in the embodiments of the present disclosure, the semiconductor devices are bonded to each other with less complexity, high process flexibility and uniformity by disposing the adjustment layer(s) of the disclosure.

### BRIEF DESCRIPTION OF THE DRAWINGS

FIG. 1A and FIG. 1B are schematic cross-sectional views of various semiconductor devices according to embodiments of the present disclosure.

FIG. 2A, FIG. 2B, FIG. 3A, FIG. 3B and FIG. 3C are partial schematic cross-sectional views of various bonded dies according to embodiments of the present disclosure.

FIG. 4A to FIG. 4E are schematic cross-sectional views of a method of fabricating a semiconductor device according to an embodiment of the present disclosure.

### DESCRIPTION OF THE EMBODIMENTS

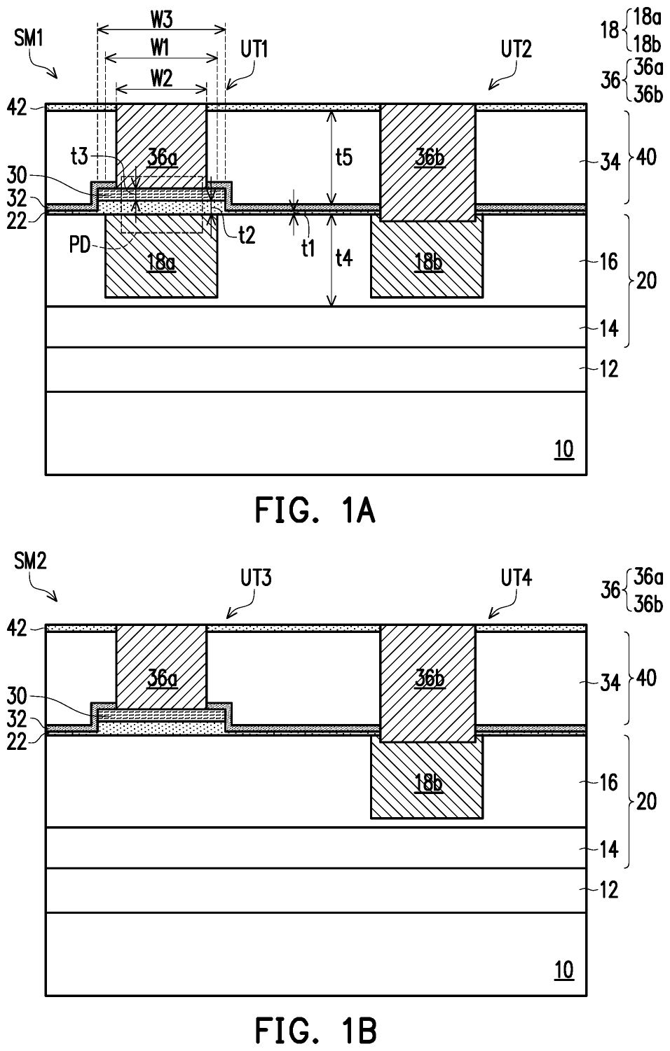

FIG. 1A and FIG. 1B are schematic cross-sectional views of various semiconductor devices according to embodiments of the present disclosure.

Referring to FIG. 1A, a semiconductor device SM1 includes units/dies UT1 and UT2. More specifically, the semiconductor device SM1 includes a substrate 10, a device layer 12, an interconnection structure 20, an adjustment layer 30 and a bonding structure 40. The interconnection structure 20, the adjustment layer 30 and the bonding structure 40 form units/dies UT1 and UT2.

The substrate 10 may be a semiconductor substrate, such as a silicon substrate. The device layer 12 may include an active device, a passive device or a combination thereof. The active device may include a metal oxide semiconductor transistor, a diode or a combination thereof. The transistor may include an N-type metal oxide semiconductor (NMOS) transistor, a P-type metal oxide semiconductor (PMOS) transistor or a complementary metal oxide semiconductor (CMOS) device. The passive device may include a capacitor, an inductor, a resistor, or a combination thereof.

The interconnection structure 20 is located over the device layer 12. The interconnection structure 20 may include multiple dielectric layers (not shown) and multiple interconnection lines (not shown) formed in the multiple dielectric layers. The multiple dielectric layers includes, for example, a bottom dielectric layer and a top dielectric layer 16. An intermediate dielectric layer (not shown) may be further included between the bottom dielectric layer 14 and the top dielectric layer 16. The bottom dielectric layer 14 and the top dielectric layer 16 may include silicon oxide. The interconnection lines include multiple contacts (not shown), multiple conductive layers (not shown) and multiple vias (not shown). The contacts are connected to the underlying device layer 12 and conductive lines of the overlying conductive layer. The vias are connected to conductive lines of the adjacent upper and lower conductive layers. The topmost conductive layer 18 of the interconnection structure 20 is located in the top dielectric layer 16. In some embodiments, the top surface of the top dielectric layer 16 is flushed with the top surface of the topmost conductive layer 18.

The bonding structure 40 is located over the interconnection structure 20. The bonding structure 40 may include a bonding layer 34 and multiple bonding pads 36. The bonding layer 34 may include silicon oxide. The bonding pads 36 are located in the bonding layer 34. The bonding pads 36 include conductor. The conductor may include metal, such as copper. In this embodiment, the multiple bonding pads 36 may include bonding pads 36a and 36b. The bonding pads 36a and 36b are disposed corresponding to the topmost conductive layers 18a and 18b of the interconnection structure 20, respectively.

The width W2 of the bonding pads 36a and 36b may be less than or equal to the width W1 of the topmost conductive layers 18a and 18b. In this embodiment, the width W2 of the bonding pad 36 may be less than the width W1 of the topmost conductive layer 18. The bonding pads 36a and 36b may be overlapped with and may be within the boundaries of the topmost conductive layers 18a and 18b.

The adjustment layer 30 is located over the topmost conductive layer 18a and the top

dielectric layer 16. The adjustment layer 30 is a patterned layer that completely covers the topmost conductive layer 18a and partially covers the top dielectric layer 16. The adjustment layer 30 is located below the bonding pad 36a. In other words, the adjustment layer 30 is sandwiched between the topmost conductive layer 18a and the bonding pad 36a, and overlapped with the topmost conductive layer 18a and the bonding pad 36a.

The width W3 of the adjustment layer 30 may be greater than or equal to the width W1 of the topmost conductive layer 18a. The width W3 of the adjustment layer 30 may be greater than or equal to the width W2 of the bonding pad 36a. In this embodiment, the width W3 of the adjustment layer 30 is greater than the width W2 of the bonding pad 36a, and greater than the width W1 of the topmost conductive layer 18a, so that the bonding pad 36a can be landed on the adjustment layer 30 and in contact with the adjustment layer 30. The adjustment layer 30 extends laterally and protrudes from the sidewall of the bonding pad 36a, and protrudes from the sidewall of the topmost conductive layer 18a. The thickness t3 of the adjustment layer 30 may be less than the thickness t4 of the top dielectric layer 16. The thickness t3 of the adjustment layer 30 may be less than the thickness t5 of the bonding layer 34.

The adjustment layer 30 may have a single-layer or multi-layer structure. The adjustment layer 30 may include a conductive layer, a semiconductor layer, an insulating layer or a combination thereof. The adjustment layer 30 may include metal, metal nitride or metal oxide. The metal nitride may include TaₓN_{y}, TiₓN_{y} or a combination thereof. The metal oxide may include TaₓO, TiₓO or a combination thereof. The adjustment layer 30 may include a high dielectric constant material, such as HfₓO_{y}, HfₓZrO_{y}, HfₓAlO_{y} or a combination thereof.

The semiconductor device SM1 may further include cap layers 22, 32 and 42. The cap layers 22 and 32 cover a portion of the top surface, the sidewall and the bottom surface of the adjustment layer 30. More specifically, the cap layer 22 covers the top surfaces of the top dielectric layer 16 and the topmost conductive layer 18a and a portion of the surface of the topmost conductive layer 18b of the interconnection structure 20. The thickness t1 of a portion of the cap layer 22 covering the top dielectric layer 16 and a portion of the topmost conductive layer 18b may be equal to or less than the thickness t2 of another portion of the cap layer 22 covering the topmost conductive layer 18a. The cap layer 32 covers the top surface and the sidewall of the cap layer 22 and extends to cover the sidewall and a portion of the top surface of the adjustment layer 30. The cap layer 32 may be a conformal layer having a substantially uniform thickness. The cap layer 42 covers the top surface of the bonding layer 34. In some embodiments, the top surface of cap layer 42 is flushed with the top surface of bonding layer 34. Each of the cap layers 22, 32, and 42 includes silicon nitride, silicon oxynitride, or a combination thereof. The materials of the cap layers 22, 32 and 42 may be the same or different.

In an embodiment of the present disclosure, the bonding pad 36a, the adjustment layer 30, the cap layer 22 and the topmost conductive layer 18a form a unit/die UT1 of the semiconductor device SM1. The bonding pad 36b and the topmost conductive layer 18b form a unit/die UT2 of the semiconductor device SM1.

In an embodiment of the present disclosure, no bonding via is provided below the bonding pad 36a of the unit/die UT1 and the bonding pad 36b of the unit/die UT2. In other words, the adjustment layer 30 and the cap layer 22 are located between and in contact with both the bonding pad 36a and the topmost conductive layer 18a, and no bonding via for electrical connection to the topmost conductive layer 18a is disposed in the adjustment layer 30 and the cap layer 22. The bonding pad 36b is in direct contact with the topmost conductive layer 18b without a bonding via.

In the present disclosure, the material of the adjustment layer 30 can be selected properly, so that the adjustment layer 30, the topmost conductive layer 18a and the bonding pad 36a of the unit/die UT1 can together form a passive device. In an embodiment in which the cap layers 22 and 32 are included, the adjustment layer 30, the topmost conductive layer 18a, the bonding pad 36a and the cap layers 22 and 32 can together form a passive device PD. The passive device PD may include a capacitor, an inductor, a resistor or a combination thereof. In other words, the passive device can also be placed in a dummy region of the chip so as to effectively utilize the chip area.

In some embodiments, the units/dies UT1 and UT2 may be disposed in a dummy region of the substrate, the adjustment layer 30 sandwiched between the topmost conductive layer 18a and the bonding pad 36a may be an insulating layer, while the topmost conductive layer 18b may be a functional conductive layer or a dummy conductive layer, and the topmost conductive layer 18b may be not present, as shown in FIG. 1B.

Referring to FIG. 1B, a semiconductor device SM2 includes units/dies UT3 and UT4. More specifically, the semiconductor device SM2 is similar to the semiconductor device SM1, but the interconnection structure 20 of the semiconductor device SM2 does not have a topmost conductive layer 18a. An adjustment layer 30 and a cap layer 22 are disposed below the bonding pad 36a. The bonding pad 36a is in direct contact with the adjustment layer 30, and no bonding via is provided in the adjustment layer 30 and the cap layer 22. There is no topmost conductive layer 18a right below the cap layer 22. The cap layer 22 is in direct contact with the top dielectric layer 16. A bonding via is not provided below the bonding pad 36b. The bonding pad 36b is in direct contact with the underlying topmost conductive layer 18b. The bonding pad 36a, the adjustment layer 30 and the cap layer 22 form a unit/die UT3 of the semiconductor device SM2. The bonding pad 36a and the topmost conductive layer 18a form a unit/die UT4 of the semiconductor device SM2. The unit/die UT4 of the semiconductor device SM2 may be the same as the unit/die UT2 of the semiconductor device SM1.

In the present disclosure, the adjustment layer 30 is disposed below the bonding pad 36a. The adjustment layer 30, the topmost conductive layer 18a and the bonding pad 36a can together form a passive device PD so as to effectively utilize the chip area. The adjustment layer 30 may be an insulating layer. In an embodiment in which the adjustment layer 30 is an insulating layer, no matter whether the topmost conductive layer 18a is present or not, the subsequent hybrid bonding process can have sufficient uniformity.

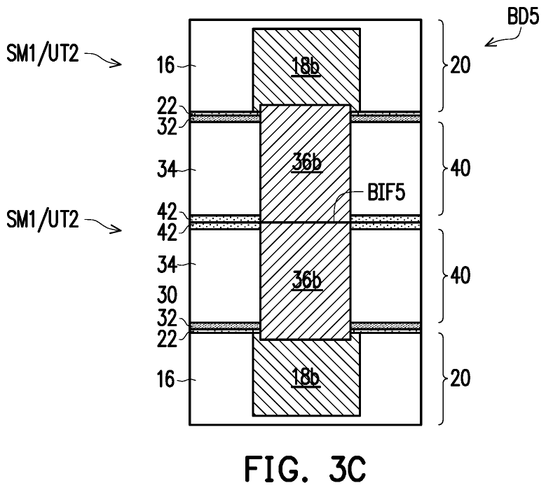

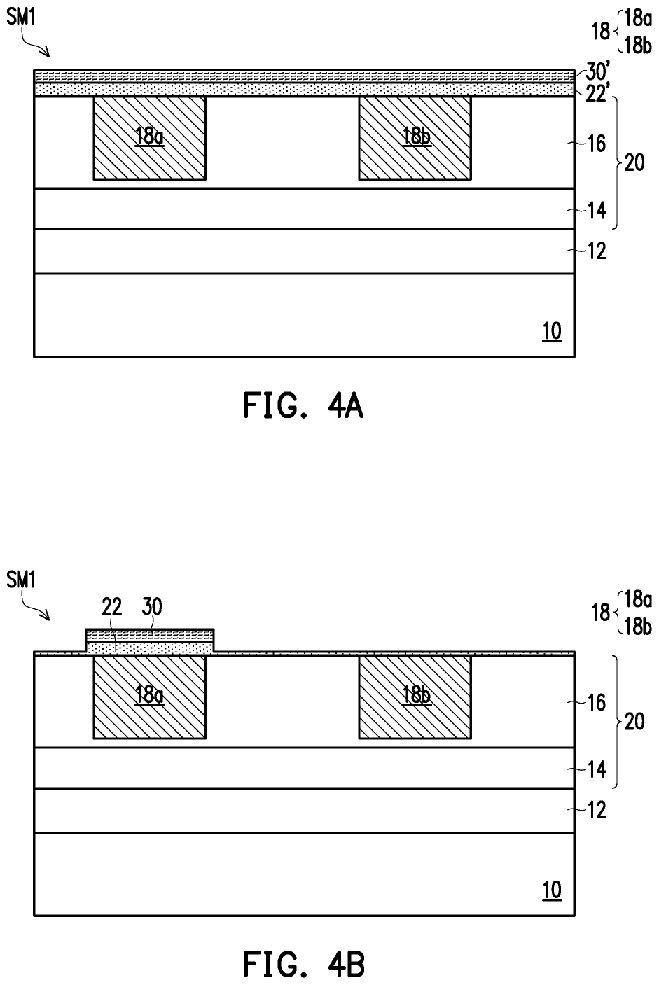

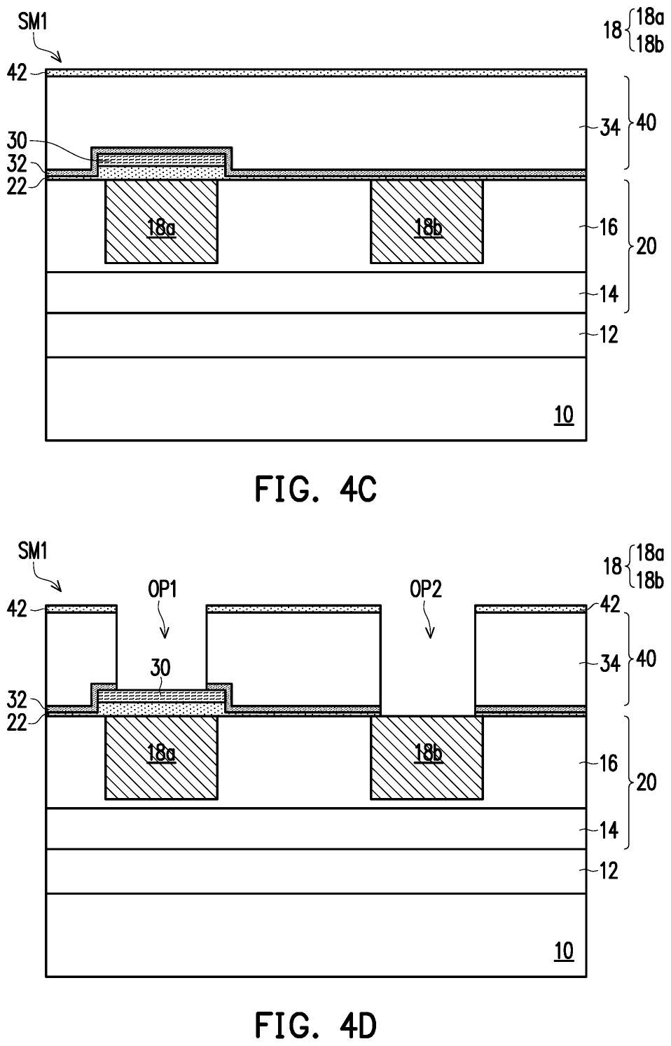

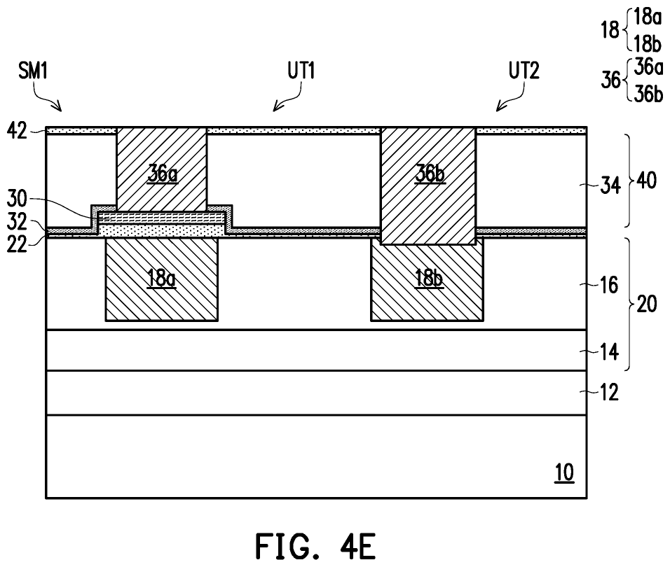

FIG. 4A to FIG. 4E are schematic cross-sectional views of a method of fabricating a semiconductor device according to an embodiment of the present disclosure.

Referring to FIG. 4A, a semiconductor device SM1 may be formed with the following method. A device layer 12 and an interconnection structure 20 are formed on a substrate 10. The device layer 12 may be formed by any known method. The interconnection structure 20 may include an bottom dielectric layer 14, a top dielectric layer 16, and interconnection lines (not shown) formed in the multilayer dielectric layers. The interconnection lines can be formed using a single damascene process or a dual damascene process. In some embodiments, a planarization process (e.g., a chemical mechanical polishing process) can be performed, so that the topmost conductive layer 18 of the interconnect lines is flushed with the top surface the top dielectric layer 16.

Referring to FIG. 4A, a cap layer 22′ and an adjustment layer 30′ are formed on the interconnection structure 20. The materials of the cap layer 22′ and the adjustment layer 30′ can be the same as those of the cap layer 22 and the adjustment layer 30 described above.

Referring to FIG. 4B, lithography and etching processes are performed to pattern the adjustment layer 30′ to form an adjustment layer 30. The location of the adjustment layer 30 corresponds to the location of the topmost conductive layer 18a. During the patterning process, the cap layer 22′ uncovered by the adjustment layer 30 is also etched, and a cap layer 22 accordingly remains.

Referring to FIG. 4C, a cap layer 32 is formed over the substrate 10. The cap layer 32 covers a portion of the surface and the sidewall of the cap layer 22 and covers the surface and the sidewall of the adjustment layer 30. Next, a bonding layer 34 of a bonding structure 40 is formed on the cap layer 32. Afterwards, a cap layer 42 is formed on the bonding layer 34. The materials of the cap layers 32 and 42 can be the same as those of the cap layers 32 and 42 described above. The materials of the cap layers 22, 32 and 42 can be the same or different.

Referring to FIG. 4D, lithography and etching processes are performed to form openings OP1 and OP2 in the cap layer 42, the bonding layer 34 and the cap layer 32. The openings OP1 and OP2 may be holes. During the etching process, an over-etching process can be used to ensure that the opening OP1 exposes the adjustment layer 30, and the opening OP2 exposes the topmost conductive layer 18b.

Referring to FIG. 4E, bonding pads 36a and 36b of the bonding structure 40 are formed in the openings OP1 and OP2. The bonding pad 36a is landed on the adjustment layer 30 and is in contact with the adjustment layer 30. The bonding pad 36b is landed on and in contact with the topmost conductive layer 18b. The method of forming the bonding pads 36a and 36b includes, for example, forming a conductive layer on the cap layer 42. The conductive layer is filled nn the opening OP1 and OP2. Then, a planarization process (e.g., a chemical mechanical polishing process) is performed to remove the conductive layer on the cap layer 42, and the remaining conductive layer in the opening OP1 and OP2 forms the bonding pads 36a and 36b.

The above-mentioned semiconductor device SM2 can be formed by a method similar to the described method, but the topmost conductive layer 18a is omitted in the top dielectric layer 16, while the topmost conductive layer 18b remains.

In the embodiment of the present disclosure, no bonding via is provided in the bonding structure 40, so the bonding pads 36a and 36b can be formed by a single damascene process, and thus, the process complexity and the production cost can be reduced.

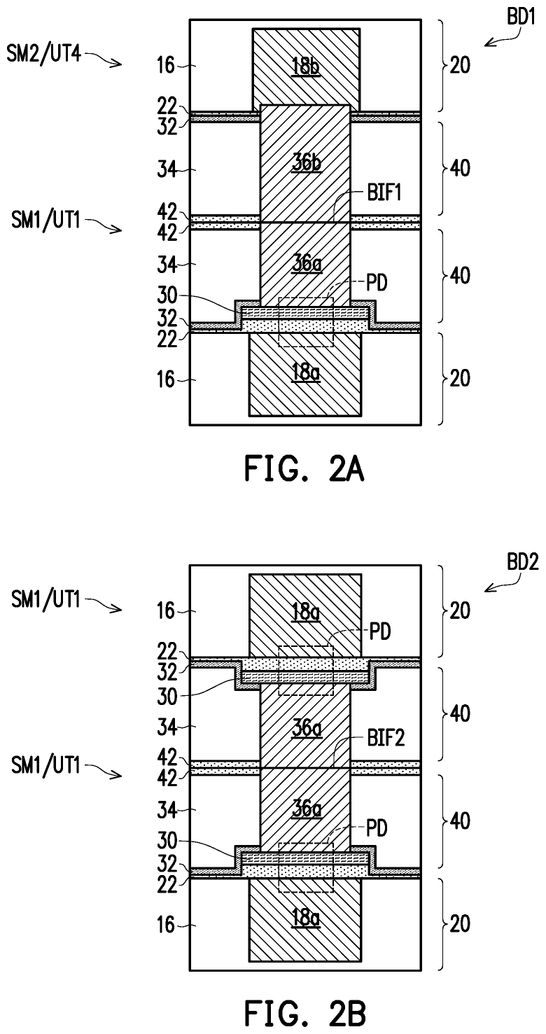

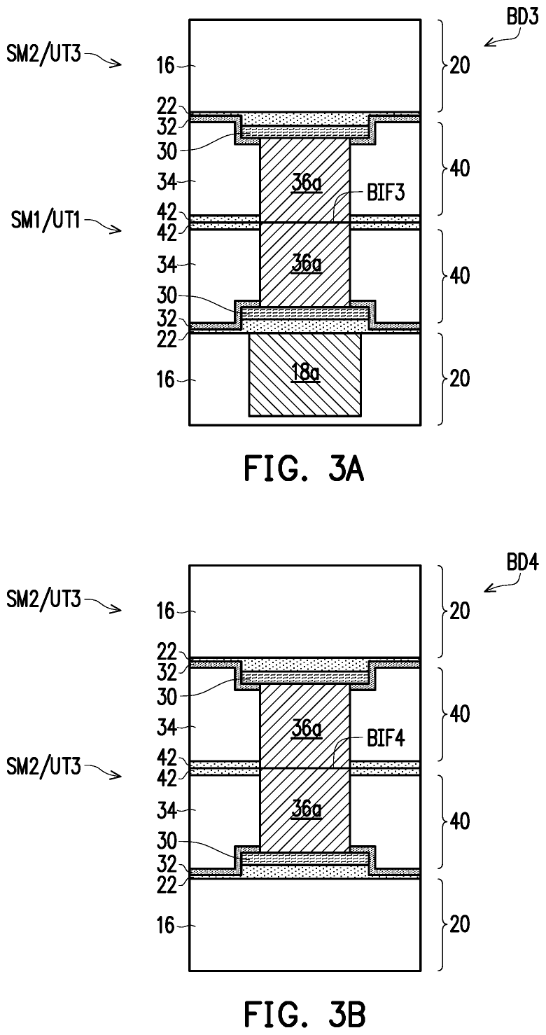

FIG. 2A, FIG. 2B, FIG. 3A, FIG. 3B and FIG. 3C are partial schematic cross-sectional views of various bonded dies according to embodiments of the present disclosure.

Referring to FIG. 2A, a unit/die UT2 of a semiconductor device SM2 is hybrid-bonded to a unit/die UT1 of a semiconductor device SM1, so as to form a bonded die BD1. Herein, the semiconductor device SM2 and the semiconductor device SM1 may be bonded by a wafer-to-wafer bonding, a die-to-wafer bonding, or a suitable method. In the bonded die BD1, the cap layer 42 of the semiconductor device SM2 is bonded to the cap layer 42 of the semiconductor device SM1. The bonding pad 36b of the semiconductor device SM2 is bonded to the bonding pad 36a of the semiconductor device SM1. The bonding pad 36b may be completely or partially overlapped with the bonding pad 36a. The bonded die BD1 may have a bonding interface BIF1. By selecting an appropriate adjustment layer 30, the bonded die BD1 can have a passive device PD. The passive device PD is in the unit/die UT1 below the bonding interface BIF1. There is no passive device in the unit/die UT2 over the bonding interface BIF1. The topmost conductive layer 18b of the unit/die UT2 of the semiconductor device SM2 may be a functional conductive layer for connecting the passive device PD to other devices.

Referring to FIG. 2B, a unit/die UT1 of a semiconductor device SM1 is hybrid-bonded to a unit/die UT1 of another semiconductor device SM1, so as to form a bonded die BD2. Herein, the semiconductor device SM1 and another semiconductor device SM1 can be bonded by a wafer-to-wafer bonding, a die-to-wafer bonding, or a suitable method. In the bonded die BD2, the cap layers 42 of the two semiconductor devices SM1 are bonded to each other. The bonding between the cap layer 42 and the cap layer 42 is a dielectric-to-dielectric bonding. The bonding pads 36a of the two semiconductor devices SM1 are bonded to each other. The bonding between the bonding pad 36a and the bonding pad 36a is a metal-to-metal bonding. The two bonding pads 36a may be completely or partially overlapped with each other. The bonded die BD2 may have a bonding interface BIF2. The materials of two adjustment layers 30 can be the same or different. By selecting an appropriate adjustment layer 30, the bonded die BD2 may have two passive devices PD respectively in the units/dies UT1 below and over the bonding interface BIF2. The two passive devices PD can be the same or different. The two passive devices PD can be both capacitors, inductors or resistors. One of the two passive devices PD may be one of a capacitor, an inductor and a resistor; and the other of the passive devices PD may be another of a capacitor, an inductor and a resistor. The two passive devices PD can be electrically connected to each other through the two connected bonding pads 36a.

Referring to FIG. 3A, a unit/die UT3 of a semiconductor device SM2 is hybrid-bonded to a unit/die UT1 of another semiconductor device SM1, so as to form a bonded die BD4. Herein, the semiconductor device SM2 and the semiconductor device SM1 may be bonded by a wafer-to-wafer bonding, a die-to-wafer bonding, or a suitable method. In the bonded die BD4, the cap layer 42 of the semiconductor device SM2 is bonded to the cap layer 42 of the semiconductor device SM1. The bonding pad 36a of the semiconductor device SM2 is bonded to the bonding pad 36a of the semiconductor device SM1. The two bonding pads 36a may be completely or partially overlapped with each other. The bonded die BD3 may have a bonding interface BIF3. The materials of two adjustment layers 30 can be the same or different. In this embodiment, the adjustment layers 30 of the unit/die UT3 and the unit/die UT1 is an insulating layer. Each of the unit/die UT3 and the unit/die UT1 is a dummy structure without a passive device. The unit/die UT3 of the semiconductor device SM2 is hybrid-bonded to the unit/die UT1 of the semiconductor device SM1 with sufficient uniformity.

Referring to FIG. 3B, a unit/die UT3 of a semiconductor device SM2 is hybrid-bonded to a unit/die UT3 of another semiconductor device SM2 to form a bonded die BD4. Herein, the semiconductor device SM2 and another semiconductor device SM2 may be bonded by a wafer-to-wafer bonding, a die-to-wafer bonding, or a suitable method. In the bonded die BD4, two cap layers 42 are bonded to each other. Two bonding pads 36a are bonded to each other. The two bonding pads 36a may be completely or partially overlapped with each other. The bonded die BD4 may have a bonding interface BIF4. The cells/die UT3 are both dummy structures. There is no passive device below and over the bonding interface BIF4 of the bonded die BD4. The materials of two adjustment layers 30 can be the same or different. Although each of the adjustment layers 30 over and below the bonding interface BIF4 is an insulating layer, the unit/die UT3 of the semiconductor device SM2 is hybrid-bonded to the unit/die UT3 of another semiconductor device SM2 with sufficient uniformity.

Referring to FIG. 3C, the bonded die BD5 may be formed by hybrid bonding of the same units/dies UT2 of two semiconductor devices SM1. Herein, the two semiconductor devices SM1 can be bonded by a wafer-to-wafer bonding, a die-to-wafer bonding, or a suitable method. In another embodiment, the bonded die BD5 can be the same units/dies UT4 of two semiconductor devices SM2 bonded to each other, or formed by a unit/die UT4 of a semiconductor device SM2 bonded to a unit/die UT2 of a semiconductor device SM1.

In the bonded die BD5, two cap layers 42 are bonded to each other. Two bonding pads 36b are bonded to each other. Two bonding pads 36b can be completely or partially overlapped with each other. The bonding pads 36b are respectively connected to the topmost conductive layers 18b. The two topmost conductive layers 18b may be functional conductive layers connected to other devices. The two topmost conductive layers 18b may be dummy conductive layers, which are not electrically connected to other devices or have electrical functions. The bonded die BD5 may have a bonding interface BIF5. There is no passive device below and over the bonding interface BIF5 of the bonded die BD5.

In the embodiments of the present disclosure, by disposing adjustment layer(s) of the disclosure, the bonding structure can merely have bonding pads without bonding vias. Therefore, the complexity of the bonding structure can be reduced and the cost of the bonding process can be reduced.

In addition, by disposing adjustment layer(s) of the disclosure, the topmost conductive layers can be provided or not provided below the bonding pads of the bonding structure, so that the bonding process can have higher flexibility and uniformity.

Furthermore, according to the selected material(s) of the adjustment layer(s), an adjustment layer, a bonding pad and a topmost conductive layer can together form a passive device, and the passive device can be disposed in the dummy region to effectively utilize the area of the chip.

What is claimed is:

1. A semiconductor device, comprising:
a substrate;
a bonding structure, located over the substrate; and
an adjustment layer, located on a bonding pad of the bonding structure.

2. The semiconductor according to claim 1, further comprising:
an interconnection structure, located between the substrate and the bonding structure;
a first cap layer, covering a dielectric layer and a topmost conductive layer of the interconnection structure; and
a second cap layer, covering the first cap layer and the adjustment layer.

3. The semiconductor device according to claim 2, wherein the adjustment layer comprises a conductive layer, a semiconductor layer, an insulating layer or a combination thereof.

4. The semiconductor device according to claim 2, wherein the bonding pad, the first cap layer, the adjustment layer, the second cap layer and the topmost conductive layer form a passive device or a dummy structure.

5. A semiconductor device, comprising:
a first die, comprising a first interconnection structure;
a second die, comprising a second interconnection structure;
a bonding structure, bonding the first die and the second die; and
a first adjustment layer, located between a first bonding pad of the bonding structure and a first topmost conductive layer of the first interconnection structure.

6. The semiconductor device according to claim 5, further comprising:
a first cap layer, covering a first dielectric layer of the first interconnection structure and the first topmost conductive layer; and
a second cap layer, covering the first cap layer and the first adjustment layer.

7. The semiconductor device according to claim 6, wherein the first bonding pad, the first cap layer, the first adjustment layer, the second cap layer and the first topmost conductive layer form a first capacitor, a first resistor or a first dummy structure.

8. The semiconductor device according to claim 5, further comprising:
a second adjustment layer, located between a second bonding pad of the bonding structure and a second topmost conductive layer of the second interconnection structure.

9. The semiconductor device according to claim 8, further comprising:
a third cap layer, covering a second dielectric layer and a second topmost conductive layer of the second interconnection structure; and
a fourth cap layer, covering the third cap layer and the second adjustment layer.

10. The semiconductor device according to claim 9, wherein each of the first adjustment layer and the second adjustment layer comprises a conductive layer, a semiconductor layer, an insulating layer or a combination thereof.

11. The semiconductor device according to claim 10, wherein a material the first adjustment layer is the same as a material of the second adjustment layer.

12. The semiconductor device according to claim 10, wherein a material of the first adjustment layer is different from a material of the second adjustment layer.

13. The semiconductor device according to claim 9, wherein the second bonding pad, the third cap layer, the second adjustment layer, the fourth cap layer and the second topmost conductive layer form a second capacitor, a second resistor or a second dummy structure.

14. A method of fabricating a semiconductor device, comprising:
forming a first die, wherein the first die comprises a first interconnection structure;
forming a second die, wherein the second die comprises a second interconnection structure;
bonding the first die and the second die through a bonding structure; and
forming a first adjustment layer between a first bonding pad of the bonding structure and a first topmost conductive layer of the first interconnection structure.

15. The method according to claim 14, further comprising:
forming a first cap layer, the first cap layer covering a first dielectric layer and a first topmost conductive layer of the first interconnection structure; and
forming a second cap layer, the second cap layer covering the first cap layer and the first adjustment layer.

16. The method according to claim 15, wherein the first bonding pad, the first cap layer, the first adjustment layer, the second cap layer and the first topmost conductive layer form a first passive device or a first dummy structure.

17. The method according to claim 15, further comprising:
forming a second adjustment layer, the second adjustment layer located between a second bonding pad of the bonding structure and a second topmost conductive layer of the second interconnection structure.

18. The method according to claim 17, further comprising:
forming a third cap layer, the third cap layer covering a second dielectric layer and a second topmost conductive layer of the second interconnection structure; and
forming a fourth cap layer, the fourth cap layer covering the third cap layer and the second adjustment layer.

19. The method according to claim 17, wherein each of the first adjustment layer and the second adjustment layer comprises a conductive layer, a semiconductor layer, an insulating layer or a combination thereof.

20. The method according to claim 17, wherein the second bonding pad, the third cap layer, the second adjustment layer, the fourth cap layer and the second topmost conductive layer form a second passive device or a second dummy structure.
